(19) United States
(12) Patent Application Publication
(10) Pub. No.: US 2026/0150760 A1
(43) Pub. Date: May 28, 2026

(54) POWER MODULE

(71) Applicant: SHINKO ELECTRIC INDUSTRIES CO., LTD., Nagano (JP)

(72) Inventor: Koji BANDO, Nagano (JP)

(21) Appl. No.: 19/391,109

(22) Filed: Nov. 17, 2025

(30) Foreign Application Priority Data
Nov. 27, 2024 (JP) 2024-205985

(51) Int. Cl. H01L 25/07; H01L 23/00; H01L 23/31; H01L 23/495; H01L 23/498; H10D 80/20

(52) U.S. Cl. CPC H10W 90/00; H10D 80/251; H10W 70/417; H10W 70/424; H10W 70/457; H10W 70/635; H10W 74/114; H10W 90/736

(57) ABSTRACT

A power module includes a first device having first and second electrodes on opposite surfaces, a second device having third and fourth electrodes on opposite surfaces, first and second insulators bonded with the first and second devices, a first conductor on a surface opposite to a bonded surface of the first insulator, penetrating the first insulator and coupled to the first electrode, a second conductor coupled to the second electrode, a third conductor bonded to the bonded surface of the first insulator and coupled to the first conductor, a fourth conductor on a surface opposite to a bonded surface of the second insulator, penetrating the second insulator and coupled to the third electrode, a fifth conductor coupled to the fourth electrode, a sixth conductor bonded to the bonded surface of the second insulator and coupled to the fourth conductor, and a seventh conductor coupling the third and fifth conductors.

### CROSS-REFERENCE TO RELATED APPLICATIONS

This application is based upon and claims priority to Japanese Patent Application No. 2024-205985, filed on Nov. 27, 2024, the entire contents of which are incorporated herein by reference.

### FIELD

Certain aspects of the embodiments discussed herein are related to power modules.

### BACKGROUND

There is a proposed power module having two semiconductor devices overlapping each other in a plan view.

Related art include International Publication Pamphlet No. WO 2024/202838, Japanese Laid-Open Patent Publication No. 2014-045010, Japanese Laid-Open Patent Publication No. 2010-129801, and International Publication Pamphlet No. WO 2015/064197, for example.

In recent years, there are increased demands to further reduce an inductance of the power module.

### SUMMARY

Accordingly, it is an object in one aspect of the embodiments of the present disclosure to reduce an inductance of a power module.

According to an aspect of the embodiments of the present disclosure, a power module includes a first semiconductor device having a first surface and a second surface opposite to the first surface, a first electrode provided on the first surface, and a second electrode provided on the second surface; a second semiconductor device having a third surface and a fourth surface opposite to the third surface, a third electrode provided on the third surface, and a fourth electrode provided on the fourth surface; a first insulating base material having a fifth surface bonded with the first semiconductor device, and a sixth surface opposite to the fifth surface; a second insulating base material having a seventh surface bonded with the second semiconductor device, and an eighth surface opposite to the seventh surface; a first conductive member penetrating the first insulating base material, electrically connected to the first electrode, and stacked on the sixth surface of the first insulating base material; a second conductive member electrically connected to the second electrode; a third conductive member bonded to the fifth surface and electrically connected to the first conductive member; a fourth conductive member penetrating the second insulating base material, electrically connected to the third electrode, and stacked on the eighth surface of the second insulating base material; a fifth conductive member electrically connected to the fourth electrode; a sixth conductive member bonded to the seventh surface and electrically connected to the fourth conductive member; and a seventh conductive member electrically connecting the third conductive member and the fifth conductive member, wherein the first conductive member is located between the first semiconductor device and the fourth conductive member, the fourth conductive member is located between the second semiconductor device and the first conductive member, and the second conductive member and the sixth conductive member overlap each other in a plan view.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a perspective view (part 1) illustrating a power module according to an embodiment;

FIG. 2 is a perspective view (part 2) illustrating the power module according to the embodiment;

FIG. 3 is a perspective view (part 1) illustrating a part of the power module according to the embodiment;

FIG. 4 is a perspective view (part 2) illustrating a part of the power module according to the embodiment;

FIG. 5 is a perspective view (part 3) illustrating a part of the power module according to the embodiment;

FIG. 6 is a perspective view (part 4) illustrating a part of the power module according to the embodiment;

FIG. 7 is a perspective view (part 5) illustrating a part of the power module according to the embodiment;

FIG. 8 is a perspective view (part 6) illustrating a part of the power module according to the embodiment;

FIG. 9 is a perspective view (part 7) illustrating a part of the power module according to the embodiment;

FIG. 10 is a cross sectional view schematically illustrating the power module according to the embodiment;

FIG. 11 is a top view schematically illustrating a part of the power module according to the embodiment;

FIG. 12 is a bottom view schematically illustrating a part of the power module according to the embodiment; and

FIG. 13 is a circuit diagram illustrating the power module according to the embodiment.

### DESCRIPTION OF EMBODIMENTS

Hereinafter, embodiments will be described in detail with reference to the accompanying drawings. In the present specification and the drawings, constituent elements having substantially the same functional configuration are designated by the same reference numerals, and a redundant description thereof may be omitted. Further, in the present disclosure, an X-axis (X1-X2 direction), a Y-axis (Y1-Y2 direction), and a Z-axis (Z1-Z2 direction) are mutually orthogonal directions. A plane including the X-axis and the Y-axis is referred to as an XY-plane, a plane including the Y-axis and the Z-axis is referred to as a YZ-plane, and a plane including the Z-axis and the X-axis is referred to as a ZX-plane. For the sake of convenience, the Z1-Z2 direction is defined as a vertical direction (or up-down direction), a Z1-side is defined as an upper side, and a Z2-side is defined as a lower side. Moreover, a plan view refers to a view of an object viewed from the Z1-side, and a planar shape refers to a shape of the object in the plan view viewed from the Z1-side. However, the power module may be used in an upside-down state or may be disposed at an arbitrary angle.

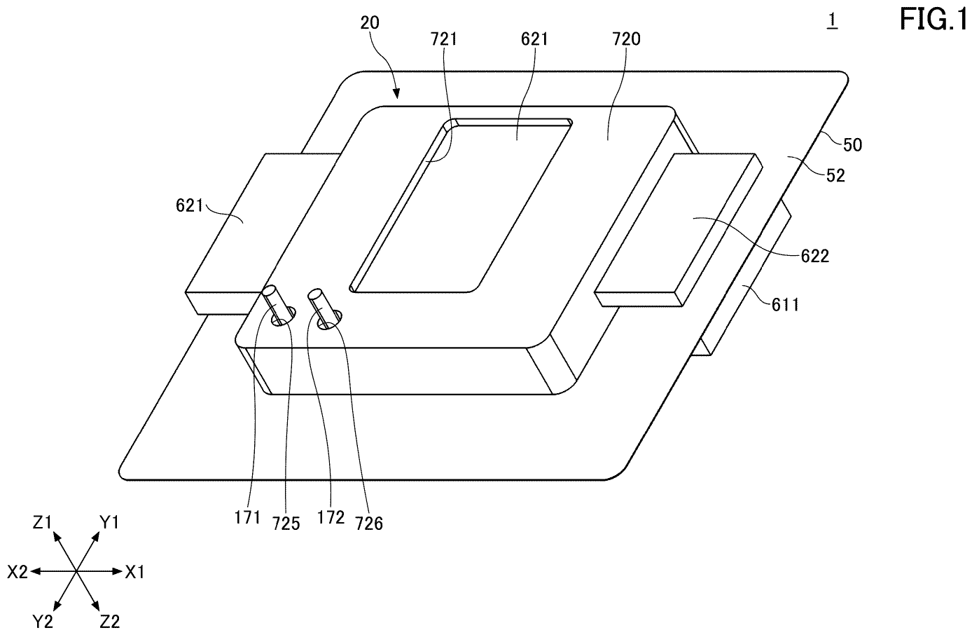

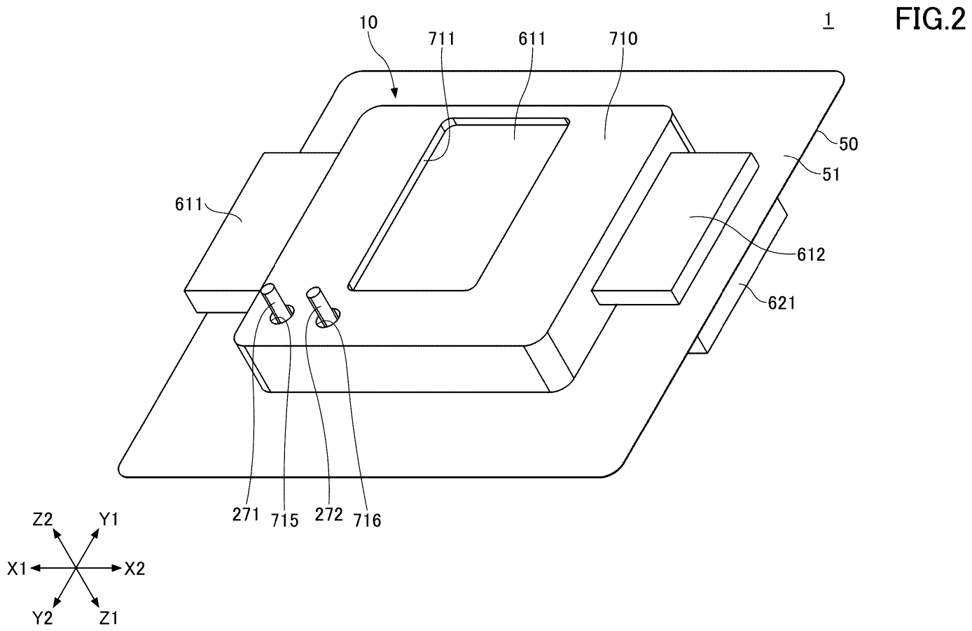

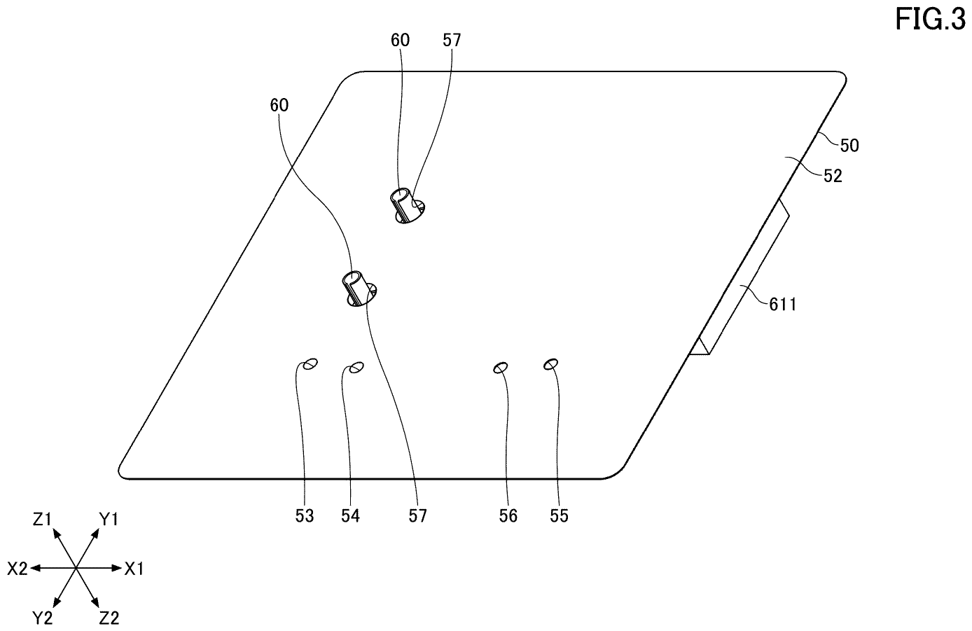

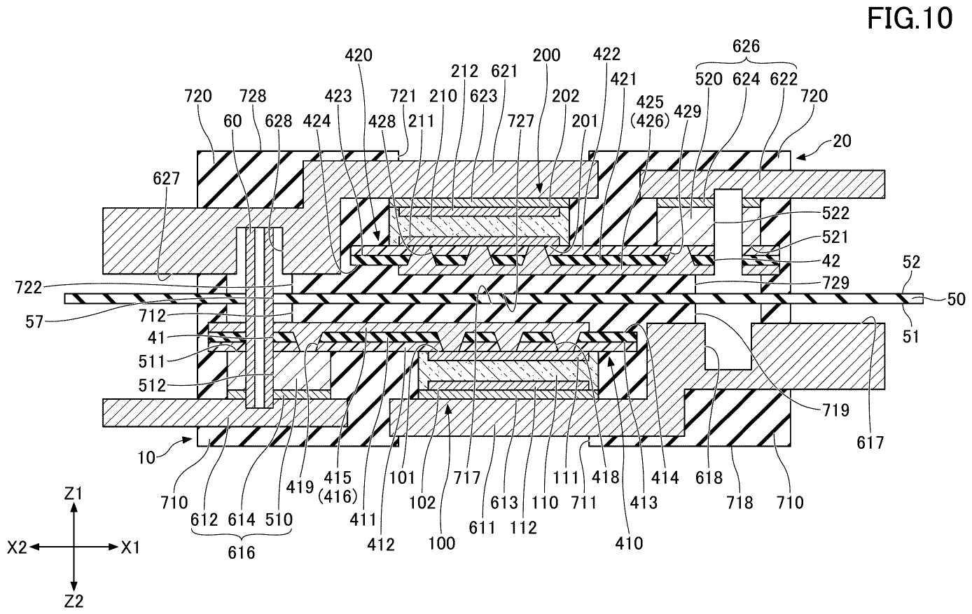

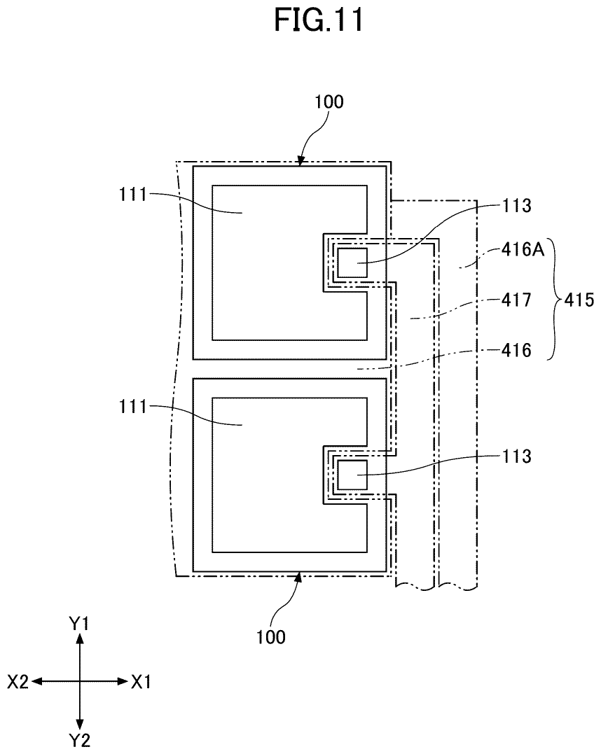

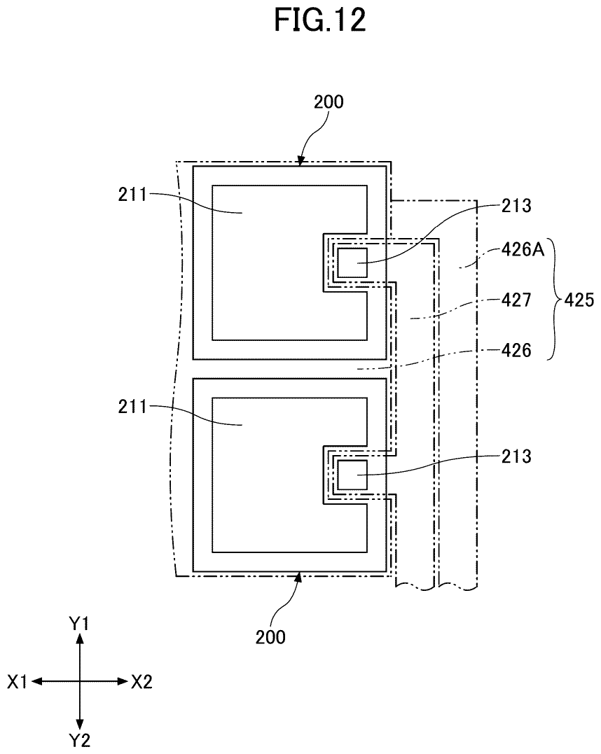

An embodiment of the present disclosure will be described. The embodiment relate to a power module. FIG. 1 and FIG. 2 are perspective views illustrating the power module according to the embodiment. FIG. 3 through FIG. 9 are perspective views illustrating parts of the power module according to the embodiment, respectively. FIG. 10 is a cross sectional view schematically illustrating the power module according to the embodiment. FIG. 11 is a top view schematically illustrating a part of the power module according to the embodiment. FIG. 12 is a bottom view schematically illustrating a part of the power module according to the embodiment.

As illustrated in FIG. 1 through FIG. 12, a power module 1 according to the embodiment includes a semiconductor package 10, a semiconductor package 20, an insulating film 50, and conductive pins 60.

The insulating film 50 is provided between the semiconductor package 10 and the semiconductor package 20. The insulating film 50 has a first surface 51 facing the semiconductor package 10, and a second surface 52 opposite to the first surface 51 and facing the semiconductor package 20. For example, the semiconductor package 10 is in contact with the first surface 51 of the insulating film 50, and the semiconductor package 20 is in contact with the second surface 52 of the insulating film 50. The semiconductor package 10 is located on the Z2-side of the insulating film 50, and the semiconductor package 20 is located on the Z1-side of the insulating film 50. A material used for the insulating film 50 is polyimide, for example.

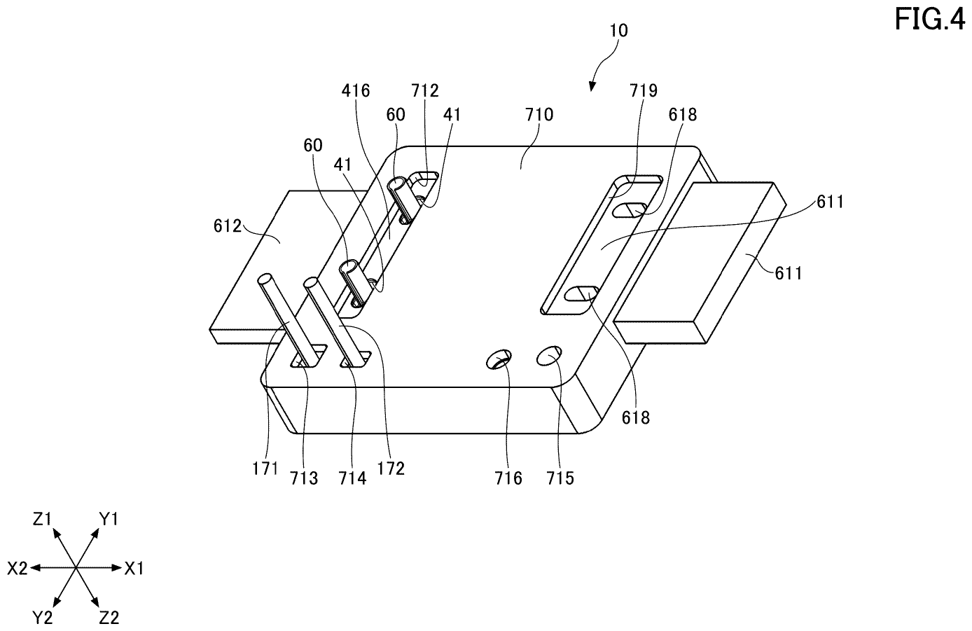

As illustrated in FIG. 4 through FIG. 6, FIG. 10, and FIG. 11, the semiconductor package 10 includes two semiconductor devices 100, a flexible wiring board 410, two shims 510, a lead terminal 611, a lead terminal 612, a control terminal 171, a sense source terminal 172, and a mold 710.

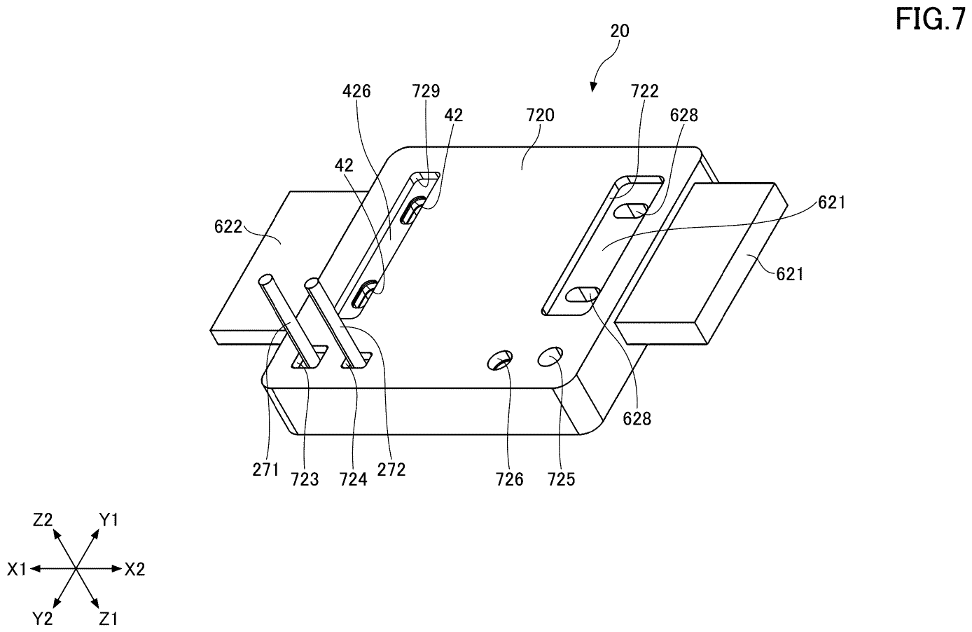

As illustrated in FIG. 7 through FIG. 10 and FIG. 12, the semiconductor package 20 includes two semiconductor devices 200, a flexible wiring board 420, two shims 520, a lead terminal 621, a lead terminal 622, a control terminal 271, a sense source terminal 272, and a mold 720.

The semiconductor devices 100 and 200 are formed using silicon (Si) or silicon carbide (SiC), for example. The semiconductor devices 100 and 200 may be formed using gallium nitride (GaN) or gallium arsenide (GaAs). For example, the semiconductor devices 100 and 200 may be insulated gate bipolar transistors (IGBTs) or metal-oxide-semiconductor field-effect transistors (MOSFETs). Planar shapes of the semiconductor devices 100 and 200 are rectangular shapes, for example. Thicknesses of the semiconductor devices 100 and 200 are approximately 50 μm to approximately 500 μm, for example.

As illustrated in FIG. 10, the semiconductor device 100 has a first surface 101 and a second surface 102 opposite to the first surface 101. The semiconductor device 100 includes a main body 110, an electrode 111, an electrode 112, and an electrode 113. The electrode 111 and the electrode 113 are provided on the first surface 101, and the electrode 112 is provided on the second surface 102. For example, the electrode 111, the electrode 112, and the electrode 113 are a source electrode, a drain electrode, and a gate electrode, respectively. The semiconductor device 100 is an example of a first semiconductor device, the first surface 101 is an example of a first surface, and the second surface 102 is an example of a second surface. The electrode 111 is an example of a first electrode, the electrode 112 is an example of a second electrode, and the electrode 113 is an example of a fifth electrode.

As illustrated in FIG. 10, the semiconductor device 200 has a first surface 201 and a second surface 202 opposite to the first surface 201. The semiconductor device 200 includes a main body 210, an electrode 211, an electrode 212, and an electrode 213. The electrode 211 and the electrode 213 are provided on the first surface 201, and the electrode 212 is provided on the second surface 202. For example, the electrode 211, the electrode 212, and the electrode 213 are a source electrode, a drain electrode, and a gate electrode, respectively. The semiconductor device 200 is an example of a second semiconductor device, the first surface 201 is an example of a third surface, and the second surface 202 is an example of a fourth surface. The electrode 211 is an example of a third electrode, the electrode 212 is an example of a fourth electrode, and the electrode 213 is an example of a sixth electrode.

A material used for the electrode 111, the electrode 112, the electrode 113, the electrode 211, the electrode 212, and the electrode 213 (hereinafter, these electrodes may be collectively referred to as “electrodes”) may be a metal such as aluminum (Al), copper (Cu), or the like, or an alloy including at least one kind of metal selected from these kinds of metals, for example. A surface treatment layer may be formed on a surface of the electrodes, as necessary. Examples of the surface treatment layer include a gold (Au) layer, a nickel (Ni) layer/Au layer (a metal layer in which a Ni layer and a Au layer are stacked in this order), a Ni layer/palladium (Pd) layer/Au layer (a metal layer in which a Ni layer, a Pd layer, and an Au layer are stacked in this order), or the like. A metal layer (electroless plating metal layer) formed by an electroless plating method, for example, can be used for the Au layer, the Ni layer, and the Pd layer. Further, the Au layer is a metal layer made of Au or an Au alloy, the Ni layer is a metal layer made of Ni or an Ni alloy, and the Pd layer is a metal layer made of Pd or a Pd alloy.

The shims 510 and 520 are metal plates, such as Cu plates or the like, for example. Thicknesses of the shims 510 and 520 are approximately the same as the thicknesses of the semiconductor devices 100 and 200.

The flexible wiring board 410 includes an insulating base material 411, an insulating adhesive layer 412, and an interconnect layer 415. The insulating base material 411 has a first surface 413 and a second surface 414 opposite to the first surface 413. The insulating adhesive layer 412 is provided on the first surface 413, and the interconnect layer 415 is provided on the second surface 414. The insulating adhesive layer 412 may be provided on the entire first surface 413. The interconnect layer 415 is stacked on the second surface 414. The insulating base material 411 is an example of a first insulating base material. The first surface 413 is an example of a fifth surface, and the second surface 414 is an example of a sixth surface.

The insulating base material 411 is a resin film, for example. Examples of a resin material used for the resin film include an insulating resin, such as a polyimide-based resin, a polyethylene-based resin, an epoxy-based resin, or the like. The insulating base material 411 has flexibility, for example. The flexibility of the material refers to a property that allows the material to be bent or deflected. A planar shape of the insulating base material 411 is a rectangular shape, for example. A thickness of the insulating base material 411 is approximately 50 μm to approximately 100 μm, for example.

The semiconductor device 100 and the shim 510 are bonded to the first surface 413 of the insulating base material 411 by the insulating adhesive layer 412. The first surface 101 of the semiconductor device 100 faces the first surface 413 of the insulating base material 411. A through hole 418 reaching the electrode 111, a through hole 419 reaching the shim 510, and a through hole (not illustrated) reaching the electrode 113 are formed in the insulating base material 411 and the insulating adhesive layer 412. A plurality of through holes 418 may be formed. A plurality of through holes 419 may be formed. The shim 510 is located at a position on the X2-side of the semiconductor device 100.

A material used for the insulating adhesive layer 412 may be an epoxy-based adhesive, a polyimide-based adhesive, a silicone-based adhesive, or the like, for example. A thickness of the insulating adhesive layer 412 is approximately 20 μm to approximately 40 μm, for example.

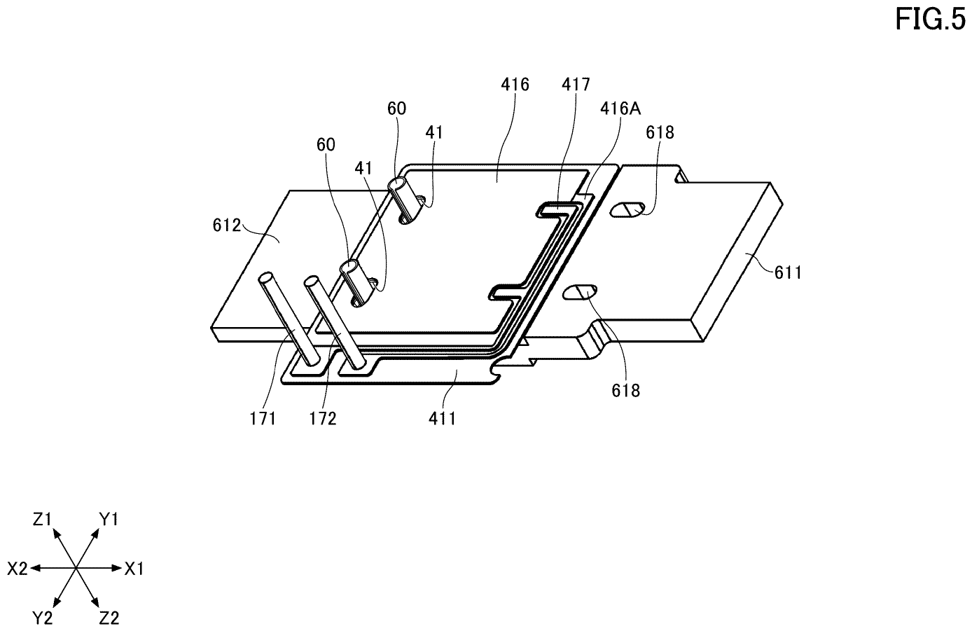

As illustrated in FIG. 5 and FIG. 10, the interconnect layer 415 includes an interconnect 416 connected to the electrode 111 via the through hole 418, an interconnect 417 connected to the electrode 113 via the through hole (not illustrated), and an interconnect 416A connected to the interconnect 416. The interconnect 416 is also connected to the shim 510 via the through hole 419. The interconnect 416 is an example of a first conductive member, and the interconnect 417 is an example of an eighth conductive member.

The interconnect 416 includes a via interconnect filling an inside of the through hole 418, a via interconnect filling an inside of the through hole 419, and an interconnect pattern formed on the second surface 414 of the insulating base material 411. The interconnect 417 includes a via interconnect filling an inside of a through hole (not illustrated), and an interconnect pattern formed on the second surface 414 of the insulating base material 411. The interconnect 416A includes an interconnect pattern formed on the second surface 414 of the insulating base material 411.

The lead terminal 611 is bonded to the electrode 112 of the semiconductor device 100 by the conductive adhesive layer 613. The lead terminal 612 is bonded to the shim 510 by the conductive adhesive layer 614. In the plan view, the lead terminal 611 extends from the semiconductor device 100 toward the X1-side, and the lead terminal 612 extends from the shim 510 toward the X2-side. The lead terminals 611 and 612 are formed of a lead frame made of Cu, for example. The conductive adhesive layers 613 and 614 are solder layers or sintered metal layers, for example. The conductive adhesive layers 613 and 614 may be made of a conductive paste. The lead terminal 611 is an example of a second conductive member. A stack 616 of the shim 510, the conductive adhesive layer 614, and the lead terminal 612 is an example of a third conductive member.

As illustrated in FIG. 5, the control terminal 171 is bonded to the interconnect 417 by a conductive adhesive layer (not illustrated), and the sense source terminal 172 is bonded to the interconnect 416A by a conductive adhesive layer (not illustrated). The control terminal 171 is electrically connected to the interconnect 417, and the sense source terminal 172 is electrically connected to the interconnect 416A. The control terminal 171 extends from the interconnect 417 toward the Z1-side, and the sense source terminal 172 extends from the interconnect 416A toward the Z1-side. The control terminal 171 is an example of a first control terminal.

As illustrated in FIG. 10, the mold 710 encapsulates the semiconductor device 100, the flexible wiring board 410, the shim 510, the lead terminal 611, and the lead terminal 612. The mold 710 has a first surface 717 and a second surface 718 opposite to the first surface 717. An end portion of the lead terminal 611 on the X1-side extends from the mold 710, and an end portion of the lead terminal 612 on the X2-side extends from the mold 710. The first surface 717 of the mold 710 faces the insulating film 50. An opening 711 (for heat dissipation) reaching a lower surface (a surface on the Z2-side) of the lead terminal 611 is formed in the second surface 718 of the mold 710. The mold 710 is an example of a first encapsulating member.

The flexible wiring board 420 includes an insulating base material 421, an insulating adhesive layer 422, and an interconnect layer 425. The insulating base material 421 has a first surface 423 and a second surface 424 opposite to the first surface 423. The insulating adhesive layer 422 is provided on the first surface 423, and the interconnect layer 425 is provided on the second surface 424. The insulating adhesive layer 422 may be provided on the entire first surface 423. The interconnect layer 425 is stacked on the second surface 424. The insulating base material 421 is an example of a second insulating base material. The first surface 423 is an example of a seventh surface, and the second surface 424 is an example of an eighth surface.

The semiconductor device 200 and the shim 520 are bonded to the first surface 423 of the insulating base material 421 by the insulating adhesive layer 422. The first surface 201 of the semiconductor device 200 faces the first surface 423 of the insulating base material 421. A through hole 428 reaching the electrode 211, a through hole 429 reaching the shim 520, and a through hole (not illustrated) reaching the electrode 213 are formed in the insulating base material 421 and the insulating adhesive layer 422. A plurality of through holes 428 may be formed. A plurality of through holes 429 may be formed. The shim 520 is located at a position on the X1-side of the semiconductor device 200.

A material used for and a thickness of the insulating base material 421 are the same as the material used for and the thickness of the insulating base material 411, for example. A material used for and a thickness of the insulating adhesive layer 422 are the same as the material used for and the thickness of the insulating adhesive layer 412, for example.

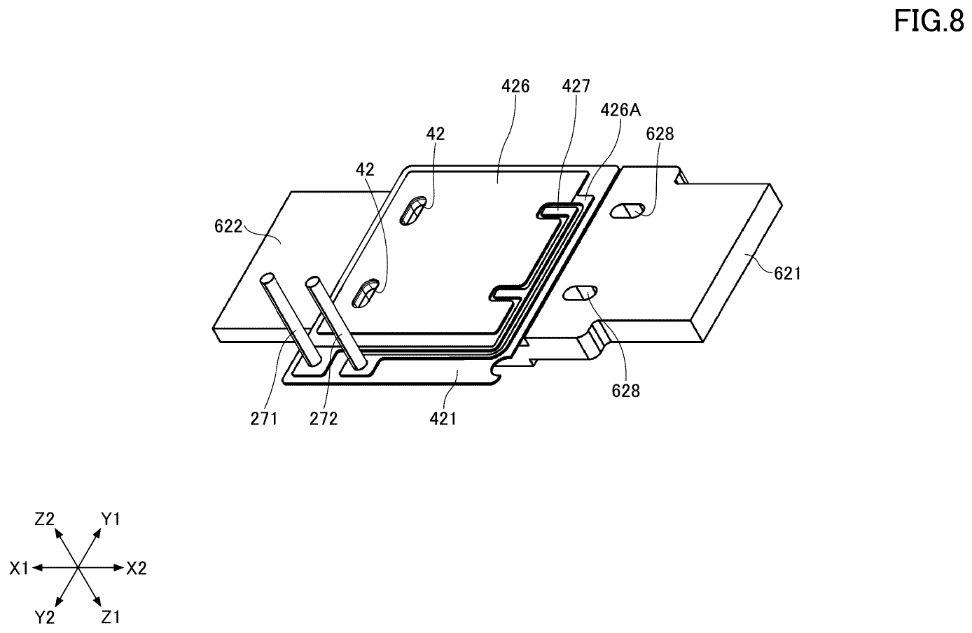

As illustrated in FIG. 8 and FIG. 10, the interconnect layer 425 includes an interconnect 426 connected to the electrode 211 via the through hole 428, an interconnect 427 connected to the electrode 213 via the through hole (not illustrated), and an interconnect 426A connected to the interconnect 426. The interconnect 426 is also connected to the shim 520 via the through hole 429. The interconnect 426 is an example of a fourth conductive member, and the interconnect 427 is an example of a ninth conductive member.

The interconnect 426 includes a via interconnect filling an inside of the through hole 428, a via interconnect filling an inside of the through hole 429, and an interconnect pattern formed on the second surface 424 of the insulating base material 421. The interconnect 427 includes a via interconnect filling an inside of a through hole (not illustrated), and an interconnect pattern formed on the second surface 424 of the insulating base material 421. The interconnect 426A includes an interconnect pattern formed on the second surface 424 of the insulating base material 421.

The lead terminal 621 is bonded to the electrode 212 of the semiconductor device 200 by a conductive adhesive layer 623. The lead terminal 622 is bonded to the shim 520 by a conductive adhesive layer 624. In the plan view, the lead terminal 621 extends from the semiconductor device 100 toward the X2-side, and the lead terminal 622 extends from the shim 520 toward the X1-side. The lead terminals 621 and 622 are formed of a lead frame made of Cu, for example. The conductive adhesive layers 623 and 624 are solder layers or sintered metal layers, for example. The conductive adhesive layers 623 and 624 may be made of a conductive paste. The lead terminal 621 is an example of a fifth conductive member. A stack 626 of the shim 520, the conductive adhesive layer 624, and the lead terminal 622 is an example of a sixth conductive member.

As illustrated in FIG. 8, the control terminal 271 is bonded to the interconnect 427 by a conductive adhesive layer (not illustrated), and the sense source terminal 272 is bonded to the interconnect 426A by a conductive adhesive layer (not illustrated). The control terminal 271 is electrically connected to the interconnect 427, and the sense source terminal 272 is electrically connected to the interconnect 426A. The control terminal 271 extends from the interconnect 427 toward the Z2-side, and the sense source terminal 272 extends from the interconnect 426A toward the Z2-side. The control terminal 271 is an example of a second control terminal.

As illustrated in FIG. 10, the mold 720 encapsulates the semiconductor device 200, the flexible wiring board 420, the shim 520, the lead terminal 621, and the lead terminal 622. The mold 720 has a first surface 727 and a second surface 728 opposite to the first surface 727. An end portion of the lead terminal 621 on the X2-side extends from the mold 720, and an end portion of the lead terminal 622 on the X1-side extends from the mold 720. The first surface 727 of the mold 720 faces the insulating film 50. An opening 721 (for heat dissipation) reaching an upper surface (a surface on the Z1-side) of the lead terminal 621 is formed in the second surface 728 of the mold 720. The mold 720 is an example of a second encapsulating member.

In the plan view, the stack 616 and the lead terminal 621 overlap each other, and the lead terminal 611 and the stack 626 overlap each other.

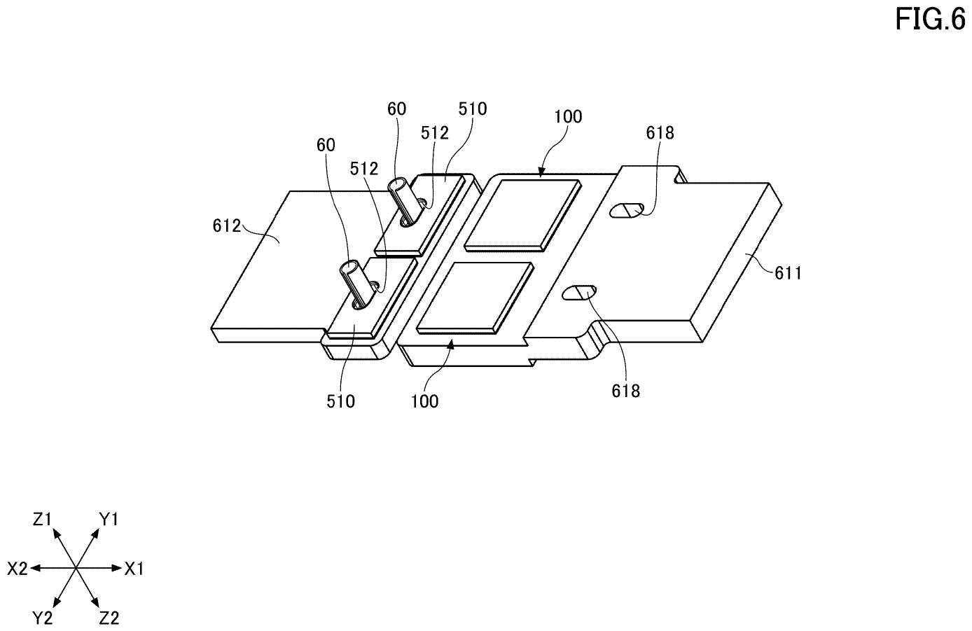

As illustrated in FIG. 10, the stack 616 has a surface 511 facing the lead terminal 621 and in contact with the insulating adhesive layer 412. A hole 512 is formed in the surface 511. A plurality of holes 512, such as two holes, for example, may be formed in the surface 511. For example, the hole 512 penetrates the shim 510 and the conductive adhesive layer 614, and reaches a point midway through a thickness direction of the lead terminal 612. As illustrated in FIG. 6, the hole 512 extends along the Y-axis, for example, and has a longitudinal direction parallel to the Y-axis and a transverse direction parallel to the X-axis. A through hole 41 overlapping the hole 512 is formed in the flexible wiring board 410. The number of through holes 41 is the same as the number of holes 512. For example, as illustrated in FIG. 5, a planar shape and size of the through hole 41 are the same as the planar shape and size of the hole 512. As illustrated in FIG. 4, an opening 712 reaching the interconnect 416 is formed in the first surface 717 of the mold 710. The opening 712 extends along the Y-axis, for example, and has a longitudinal direction parallel to the Y-axis and a transverse direction parallel to the X-axis. For example, all of the through holes 41 and the holes 512 are located inside the opening 712 in the plan view. The surface 511 is an example of a ninth surface, the hole 512 is an example of a first hole, and the Y-axis is an example of a first axis.

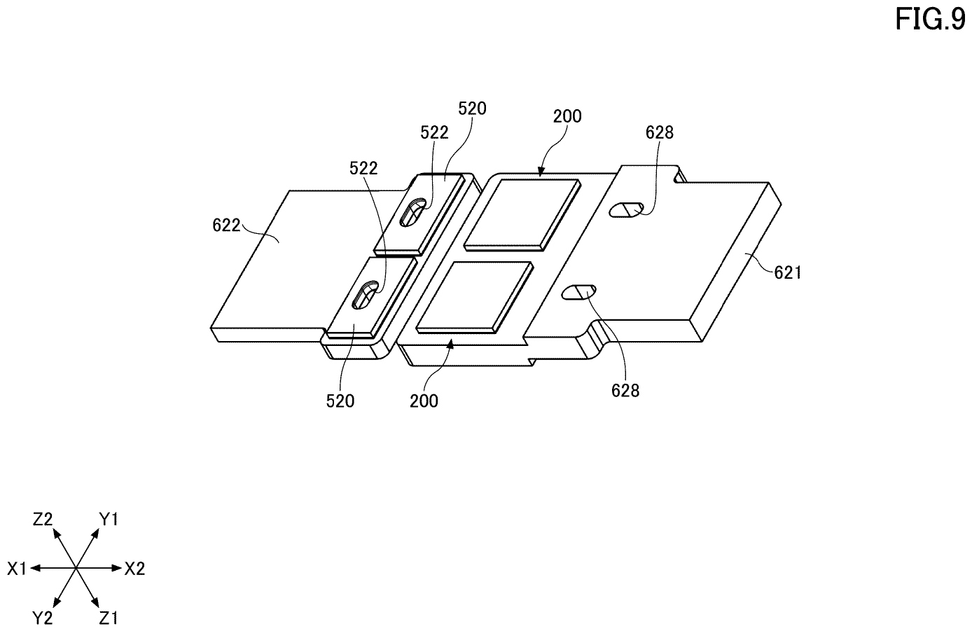

As illustrated in FIG. 10, the lead terminal 621 has a surface 627 facing the stack 616. A hole 628 is formed at a position separated from the flexible wiring board 420 in the plan view of the surface 627. The number of holes 628 that are formed is the same as the number of holes 512 that are formed. The hole 628 reaches a point midway through a thickness direction of the lead terminal 621. As illustrated in FIG. 9, the hole 628 extends along the X-axis, for example, and has a longitudinal direction parallel to the X-axis and a transverse direction parallel to the Y-axis. The hole 628 intersects the hole 512 in the plan view. For example, the hole 512 and the hole 628 are perpendicular to each other in the plan view. As illustrated in FIG. 7, an opening 722 reaching the lead terminal 621 is formed in the first surface 727 of the mold 720. The opening 722 extends along the Y-axis, for example, and has a longitudinal direction parallel to the Y-axis and a transverse direction parallel to the X-axis. For example, all the holes 628 are located inside the opening 722 in the plan view. The surface 627 is an example of a tenth surface, the hole 628 is an example of a second hole, and the X-axis is an example of a second axis.

As illustrated in FIG. 4, an opening 713 reaching the interconnect 417 and an opening 714 reaching the interconnect 416A are formed in the first surface 717 of the mold 710. Further, the mold 710 is provided with through holes 715 and 716 penetrating the mold 710 along the Z-axis. In the plan view, the through hole 715 overlaps the interconnect 427, and the through hole 716 overlaps the interconnect 426A.

As illustrated in FIG. 7, an opening 723 reaching the interconnect 427 and an opening 724 reaching the interconnect 426A are formed in the first surface 727 of the mold 720. Further, the mold 720 is provided with through holes 725 and 726 penetrating the mold 720 along the Z-axis. In the plan view, the through hole 725 overlaps the interconnect 417, and the through hole 726 overlaps the interconnect 416A. In the plan view, the opening 723 overlaps the through hole 715, the opening 724 overlaps the through hole 716, the through hole 725 overlaps the opening 713, and the through hole 726 overlaps the opening 714.

As illustrated in FIG. 3 and FIG. 10, the insulating film 50 is formed with through holes 53, 54, 55, 56, and 57 penetrating the insulating film 50 along the Z-axis. In the plan view, the through hole 53 overlaps the opening 713 and the through hole 725, the through hole 54 overlaps the opening 714 and the through hole 726, the through hole 55 overlaps the through hole 715 and the opening 723, and the through hole 56 overlaps the through hole 716 and the opening 724. The number of through holes 57 that are formed is the same as the number of holes 512 that are formed. In the plan view, the through hole 57 overlaps the hole 512, the through hole 41, the opening 712, the opening 722, and the hole 628.

As illustrated in FIG. 1, the control terminal 171 penetrates the insulating film 50 and the mold 720, and extends above the second surface 728 of the mold 720 through the opening 713, the through hole 53, and the through hole 725. The sense source terminal 172 penetrates the insulating film 50 and the mold 720, and extends to a position above the second surface 728 of the mold 720 through the opening 714, the through hole 54, and the through hole 726. As illustrated in FIG. 2, the control terminal 271 penetrates the insulating film 50 and the mold 710, and extends to a position below the second surface 718 of the mold 710 through the opening 723, the through hole 55, and the through hole 715. The sense source terminal 272 penetrates the insulating film 50 and the mold 710, and extends to a position below the second surface 718 of the mold 710 through the opening 724, the through hole 56, and the through hole 716.

A material used for the conductive pins 60 may be a metal such as aluminum (Al), copper (Cu), or the like, or an alloy including at least one kind of metal selected from these kinds of metals, for example. The conductive pins 60 are in contact with the stack 616 and the lead terminal 621, and electrically connect the stack 616 and the lead terminal 621. The conductive pins 60 penetrate the through holes 41, the openings 712, the through holes 57, and the openings 722, and one end portions (end portions on the Z2-side) of the conductive pins 60 are inserted into the holes 512 of the stack 616, and the other end portions (end portions on the Z1-side) are inserted into the holes 628 of the lead terminals 621. The conductive pins 60 are fitted into the holes 512 and 628, and are in contact with inner wall surfaces of (walls defining) the holes 512 and inner wall surfaces of (walls defining) the holes 628. The conductive pins 60 have a substantially cylindrical shape with a slit formed along a longitudinal direction thereof, for example. In this case, a cross section of each conductive pin 60 perpendicular to the longitudinal direction have an arc shape. The conductive pins 60 may have a cylindrical shape or a columnar shape. The conductive pins 60 may have a polygonal cylindrical shape or a polygonal prism shape. When the conductive pins 60 have the cylindrical shape which may be hollow, the conductive pins 60 are more easily deformed elastically compared the conductive pins 60 having the columnar shape, and the cylindrical conductive pins 60 can more easily make contact with the stack 616 and the lead terminal 621. In a case where the conductive pins 60 have the cylindrical shape with the slit is formed along the longitudinal direction thereof, the conductive pins 60 are even more easily deformed elastically, and can even more easily make contact with the stack 616 and the lead terminal 621. The easier the conductive pins 60 can make contact with the stack 616 and the lead terminal 621, the higher a reliability of the connection becomes. The conductive pins 60 are examples of a seventh conductive member.

As illustrated in FIG. 10, the stack 626 has a surface 521 facing the lead terminal 622 and in contact with the insulating adhesive layer 422. The surface 521 may have a hole 522 formed therein. A plurality of holes 522, such as two holes, for example, may be formed. For example, the hole 522 penetrates the shim 520 and the conductive adhesive layer 624, and reaches a point midway through a thickness direction of the lead terminal 622. As illustrated in FIG. 9, the hole 522 extends along the Y-axis, for example, and has a longitudinal direction parallel to the Y-axis and a transverse direction parallel to the X-axis. A through hole 42 overlapping the hole 522 may be formed in the flexible wiring board 420. The number of through holes 42 that are formed may be the same as the number of holes 522 that are formed. For example, as illustrated in FIG. 8, the planar shape and size of the through hole 42 are the same as the planar shape and size of the hole 522. As illustrated in FIG. 7, an opening 729 reaching the interconnect 426 may be formed in the first surface 727 of the mold 720. The opening 729 extends along the Y-axis, for example, and has a longitudinal direction parallel to the Y-axis and a transverse direction parallel to the X-axis. For example, all the through holes 42 and the holes 522 are located inside the opening 729 in the plan view.

As illustrated in FIG. 10, the lead terminal 611 has a surface 617 facing the stack 626. A hole 618 may be formed at a position separated from the flexible wiring board 410 in the plan view of the surface 617. The number of holes 618 may be the same as the number of holes 522. The hole 618 reaches a point midway through a thickness direction of the lead terminal 611. As illustrated in FIG. 5, the hole 618 extends along the X-axis, for example, and has a longitudinal direction parallel to the X-axis and a transverse direction parallel to the Y-axis. The hole 618 intersects the hole 522 in the plan view. For example, the hole 522 and the hole 618 are perpendicular to each other in the plan view. As illustrated in FIG. 4, an opening 719 reaching the lead terminal 611 may be formed in the first surface 717 of the mold 710. The opening 719 extends along the Y-axis, for example, and has a longitudinal direction parallel to the Y-axis and a transverse direction parallel to the X-axis. For example, all the holes 618 are located inside the opening 719 in the plan view.

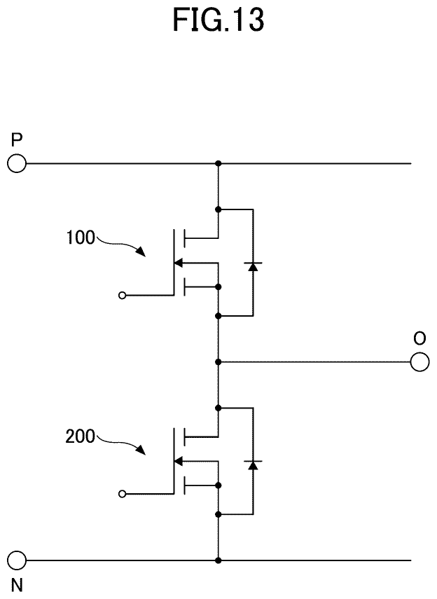

Next, a circuit configuration of the power module 1 according to the embodiment will be described. FIG. 13 is a circuit diagram illustrating the power module according to the embodiment. Although one semiconductor device 100 of the two semiconductor devices 100 and one semiconductor device 200 of the two semiconductor devices 200 are illustrated in FIG. 13 for the sake of convenience, the two semiconductor devices 100 are mutually connected in parallel, and the two semiconductor devices 200 are mutually connected in parallel. The power module 1 includes a half-bridge circuit illustrated in FIG. 13.

As illustrated in FIG. 13, the electrode 112 of the semiconductor device 100 is electrically connected to the lead terminal 611 as a P terminal, and the electrode 211 of the semiconductor device 200 is electrically connected to the lead terminal 622 as an N terminal via the interconnect 426 and the shim 520. The electrode 111 of the semiconductor device 100 is electrically connected to the lead terminal 612 as an O terminal via the interconnect 416 and the shim 510, and the electrode 212 of the semiconductor device 200 is electrically connected to the lead terminal 621 as the O terminal. The lead terminal 612 and the lead terminal 621 are electrically connected to each other via the conductive pin 60. The P terminal is an input terminal on the positive electrode side, the N terminal is an input terminal on the negative electrode side, and the O terminal is an output terminal. Accordingly, currents flow through the lead terminal 611 and the stack 626 in opposite directions.

In addition, the electrode 113 of the semiconductor device 100 is electrically connected to the control terminal 171 via the interconnect 417, and the electrode 213 of the semiconductor device 200 is electrically connected to the control terminal 271 via the interconnect 427. Hence, a control signal from the control terminal 171 is input to the electrode 113 of the semiconductor device 100, and a control signal from the control terminal 271 is input to the electrode 213 of the semiconductor device 200.

As described above, in the power module 1, the semiconductor device 100 is bonded to the first surface 413 of the insulating base material 411, the interconnect 416 is stacked on the second surface 414 of the insulating base material 411, the electrode 111 of the semiconductor device 100 is electrically connected to the interconnect 416, and the electrode 112 of the semiconductor device 100 is electrically connected to the lead terminal 611. The semiconductor device 200 is bonded to the first surface 423 of the insulating base material 421, the interconnect 426 is stacked on the second surface 424 of the insulating base material 421, the electrode 211 of the semiconductor device 200 is electrically connected to the interconnect 426, and the electrode 212 of the semiconductor device 200 is electrically connected to the lead terminal 621. The interconnect 416 and the lead terminal 621 are electrically connected to each other via the stack 616 and the conductive pins 60. The half-bridge circuit is configured in this manner. In addition, the interconnect 416 is located between the semiconductor device 100 and the interconnect 426, and the interconnect 426 is located between the semiconductor device 200 and the interconnect 426. Further, the lead terminal 611 and the stack 626 overlap each other in the plan view. Accordingly, a distance between the lead terminal 611 and the stack 626 through which currents flow in opposite directions can be reduced, and the inductance of the power module 1 can be significantly reduced. Moreover, the areas occupied by the lead terminals 611 and 622 can be reduced when compared to a configuration in which the lead terminals 611 and 622 are arranged side by side in the plan view. Hence, according to the present embodiment, a compact power module 1 can be obtained. In addition, because the influence on the size of the entire power module 1 is small even if widths of the lead terminals 611 and 622 in the Y1-Y2 direction are increased within ranges of widths of the molds 710 and 720 in the Y1-Y2 direction, interconnect resistances of the lead terminals 611 and 622 can be reduced by increasing the widths of the lead terminals 611 and 622 in the Y1-Y2 direction.

Further, because the X-axis is inclined from the Y-axis, and the Y-axis along which the hole 512 extends and the X-axis along which the hole 628 extends intersect each other in the plan view, even if a positional error occurs between the semiconductor package 10 and the semiconductor package 20 on the XY-plane, the conductive pins 60 are likely to be fitted into the holes 512 and 628.

Moreover, because the insulating film 50 is provided between the semiconductor package 10 having the interconnect 416 and the lead terminal 611 and the semiconductor package 20 having the interconnect 426 and the stack 626, it is possible to easily prevent a short circuit from occurring between the interconnect 416 or the lead terminal 611 and the interconnect 426 or the stack 626.

The hole 618 and the opening 719 may not be formed in the semiconductor package 10, and the hole 522, the through hole 42, and the opening 729 may not be formed in the semiconductor package 20. However, in the case where the hole 618 and the opening 719 are formed in the semiconductor package 10, and the hole 522, the through hole 42, and the opening 729 are formed in the semiconductor package 20, the semiconductor packages 10 and 20 may have the same configuration, thereby making the semiconductor packages 10 and 20 suitable for mass production.

The openings 711 and 721 contribute to heat dissipation. For example, the power module 1 is mounted on a heat sink so that the opening 711 or 721 faces the heat sink, and a thermal interface material (TIM) is provided between the lead terminal 611 or 621 and the heat sink.

According to the disclosed technique, an inductance of a power module can be reduced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A power module comprising:
a first semiconductor device having a first surface and a second surface opposite to the first surface, a first electrode provided on the first surface, and a second electrode provided on the second surface;
a second semiconductor device having a third surface and a fourth surface opposite to the third surface, a third electrode provided on the third surface, and a fourth electrode provided on the fourth surface;
a first insulating base material having a fifth surface bonded with the first semiconductor device, and a sixth surface opposite to the fifth surface;
a second insulating base material having a seventh surface bonded with the second semiconductor device, and an eighth surface opposite to the seventh surface;
a first conductive member penetrating the first insulating base material, electrically connected to the first electrode, and stacked on the sixth surface of the first insulating base material;
a second conductive member electrically connected to the second electrode;
a third conductive member bonded to the fifth surface and electrically connected to the first conductive member;
a fourth conductive member penetrating the second insulating base material, electrically connected to the third electrode, and stacked on the eighth surface of the second insulating base material;
a fifth conductive member electrically connected to the fourth electrode;
a sixth conductive member bonded to the seventh surface and electrically connected to the fourth conductive member; and
a seventh conductive member electrically connecting the third conductive member and the fifth conductive member, wherein:
the first conductive member is located between the first semiconductor device and the fourth conductive member,
the fourth conductive member is located between the second semiconductor device and the first conductive member, and
the second conductive member and the sixth conductive member overlap each other in a plan view.

2. The power module as claimed in claim 1, wherein:
the third conductive member and the fifth conductive member overlap each other in the plan view,
the third conductive member has a ninth surface facing the fifth conductive member and formed with a first hole,
the fifth conductive member has a tenth surface facing the third conductive member and formed with a second hole, and
the seventh conductive member is fitted into the first hole and the second hole.

3. The power module as claimed in claim 2, wherein:
in the plan view, the first hole extends along a first axis, and
in the plan view, the second hole extends along a second axis inclined from the first axis.

4. The power module as claimed in claim 3, wherein the first axis and the second axis are perpendicular to each other.

5. The power module as claimed in claim 2, wherein the seventh conductive member is in contact with an inner wall surface of the first hole and an inner wall surface of the second hole.

6. The power module as claimed in claim 1, further comprising:
an insulating film provided between the first conductive member and the second conductive member, and between the fourth conductive member and the sixth conductive member.

7. The power module as claimed in claim 6, wherein:
the first semiconductor device includes a fifth electrode provided on the first surface,
the second semiconductor device includes a sixth electrode provided on the third surface,
the power module further comprising:
an eighth conductive member penetrating the first insulating base material, electrically connected to the fifth electrode, and stacked on the sixth surface of the first insulating base material;
a ninth conductive member penetrating the second insulating base material, electrically connected to the sixth electrode, and stacked on the eighth surface of the second insulating base material;
a first control terminal electrically connected to the eighth conductive member;
a second control terminal electrically connected to the ninth conductive member;
a first encapsulating member encapsulating the first semiconductor device, the first conductive member, the second conductive member, the third conductive member, and the eighth conductive member;
a second encapsulating member encapsulating the second semiconductor device, the fourth conductive member, the fifth conductive member, the sixth conductive member, and the ninth conductive member, wherein:
the first control terminal penetrates the insulating film and the second encapsulating member, and
the second control terminal penetrates the insulating film and the first encapsulating member.

8. The power module as claimed in claim 1, wherein the seventh conductive member has a substantially cylindrical shape with a slit formed along a longitudinal direction thereof.

9. The power module as claimed in claim 1, wherein the seventh conductive member is made of a material selected from a group consisting of aluminum, copper, and an alloy including at least one of aluminum or copper.
